(19) United States
(12) Patent Application Publication
(10) Pub. No.: US 2014/0126599 A1
(43) Pub. Date: May 8, 2014

(54) (Al,In,B,Ga)N BASED SEMIPOLAR AND NONPOLAR LASER DIODES WITH POLISHED FACETS

(71) Applicant: THE REGENTS OF THE UNIVERSITY OF CALIFORNIA, OAKLAND, CA (US)

(72) Inventors: Po Shan Hsu, Arcadia, CA (US); Jeremiah J. Weaver, Tujunga, CA (US); Steven P. DenBaars, Goleta, CA (US); James S. Speck S. Speck, Goleta, CA (US); Shuji Nakamura, Santa Barbara, CA (US)

(21) Appl. No.: 14/065,736

(22) Filed: Oct. 29, 2013

Related U.S. Application Data
(60) Provisional application No. 61/723,040, filed on Nov. 6, 2012.

(51) Int. Cl. H01S 5/10

(52) U.S. Cl. CPC H01S 5/1082
USPC 372/44.011; 438/26

(57) ABSTRACT

An (Al,In,B,Ga)N or III-nitride based laser diode epitaxially grown on orientations other than a c-plane orientation, namely various semipolar and nonpolar orientations, and having polished facets. The semipolar orientation may be a semipolar (11-22), (11-2-2), (101-1), (10-1-1), (20-21), (20-2-1), (30-31) or (30-3-1) orientation, and the nonpolar orientation may be a nonpolar (10-10) or (11-20) orientation. The facets are chemically mechanically or mechanically polished.

### CROSS REFERENCE TO RELATED APPLICATIONS

This application claims the benefit under 35 U.S.C Section 119(e) of the following co-pending and commonly-assigned patent application:

U.S. Provisional Patent Application Ser. No. 61/723,040, filed on Nov. 6, 2012, by Po Shan Hsu, Jeremiah J. Weaver, Steven P. DenBaars, James S. Speck, and Shuji Nakamura, and entitled “(Al,In,B,Ga)N BASED SEMIPOLAR AND NONPOLAR LASER DIODES WITH POLISHED FACETS,” attorney's docket number 30794.470-US-P1 (2013-273-1);

which application is incorporated by reference herein.

This application is related to the following co-pending and commonly-assigned U.S. patent applications:

U.S. Utility patent application Ser. No. 13/659,191, filed Oct. 24, 2012, by Matthew T. Hardy, Po Shan Hsu, Steven P. DenBaars, James S. Speck, and Shuji Nakamura, entitled “A HOLE BLOCKING LAYER FOR THE PREVENTION OF HOLE OVERFLOW AND NON-RADIATIVE RECOMBINATION AT DEFECTS OUTSIDE THE ACTIVE REGION,” attorney's docket number 30794.434-US-U1 (2012-239), which application claims the benefit under 35 U.S.C. Section 119(e) of the following co-pending and commonly-assigned applications: U.S. Provisional Patent Application Ser. No. 61/550,870, filed Oct. 24, 2011, by Matthew T. Hardy, Po Shan Hsu, Steven P. DenBaars, James S. Speck, and Shuji Nakamura, entitled “A HOLE BLOCKING LAYER FOR THE PREVENTION OF HOLE OVERFLOW AND NON-RADIATIVE RECOMBINATION AT DEFECTS OUTSIDE THE ACTIVE REGION,” attorney's docket number 30794.434-US-P1 (2012-239); and U.S. Provisional Patent Application Ser. No. 61/550,874, filed Oct. 24, 2011, by Po Shan Hsu, Matthew T. Hardy, Steven P. DenBaars, James S. Speck, and Shuji Nakamura, entitled “NONPOLAR/SEMIPOLAR (AL,IN,B,GA)N LASERS WITH STRESS RELAXATION AT THE P-CLADDING/P-WAVEGUIDING AND N-CLADDING/N-WAVEGUIDING HETEROINTERFACES,” attorney's docket number 30794.437-US-P1 (2012-247);

all of which applications are incorporated by reference herein.

### BACKGROUND OF THE INVENTION

1. Field of the Invention

This invention relates to laser diodes (LDs) having polished facets and a method of fabricating laser diodes with polished facets.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Laser diodes incorporate a gain medium (active region) in a resonant cavity. Photons propagating in the gain medium can stimulate radiative transitions and be amplified. Facets can act as optical cavity mirrors for the laser diode, reflecting the optical radiation back and forth between the cavity mirrors. A laser beam is produced at the point where the gain exceeds the losses of the cavity. See, e.g., [1], [2] for further information.

Previously, (Al,In,B,Ga)N laser diodes have been grown on readily available c-plane sapphire substrates or on expensive SiC or bulk GaN substrates. Such (Al,In,B,Ga)N laser diodes are grown along the polar [0001] c-orientation of the (Al,In,B,Ga)N semiconductor material.

Recently, (Al,In,B,Ga)N laser diodes emitting in the violet, blue, and green emission regions have been grown on various nonpolar or semipolar orientations of the (Al,In,B,Ga)N semiconductor material. (Al,In,B,Ga)N laser diodes grown on various semipolar and nonpolar orientations have much lower polarization-induced electric fields as compared to those grown on the polar [0001] c-orientation. Moreover, quantum wells grown on semipolar and nonpolar orientations have significantly lower effective hole masses than those grown on the polar [0001] c-orientation. This leads to a reduction in the threshold of semipolar and nonpolar (Al,In,B,Ga)N laser diodes as compared to polar (Al,In,B,Ga)N laser diodes.

In laser diodes, one of the most difficult processing steps is the formation of high quality facets for the resonant cavity. The reflectivity of these facets needs to be high, the angle of the facet must be precisely determined, and damage from processing should be kept to a minimum to ensure the quality of the active region.

Polar (Al,In,B,Ga)N laser diodes grown on sapphire substrates usually employ etched facets, while such devices grown on SiC or bulk GaN substrates usually have cleaved facets.

Facets formed by cleaving are usually high quality, but must rely on the presence of a convenient cleave plane in the desired direction. In situations where cleaved facets are not possible (e.g., the lack of an appropriate cleavage plane, the existence of a substrate that is lattice-mismatched from the active area material, the desire to form integrated laser arrays, etc.), etching may be used to form the facets.

The use of wet etching to form facets has limitations, since many wet etchants are crystallographic. Consequently, wet etching may produce etched sidewalls at angles that are determined by crystallographic planes, which are not necessarily the optimal angle for the facet.

Dry etching, on the other hand, can damage the active region material, degrading the laser diode's performance. Moreover, it is challenging to both produce mirror-smooth surfaces and achieve the correct facet angle with dry etching. This leads to scattering loss, and consequently, reduced reflectivity at the facets, resulting in inferior device performance.

(Al,In,B,Ga)N laser diodes grown on various semipolar and nonpolar orientations may employ cleaving or etching to form the facets. For example, in semipolar (11-22) lasers, it is desirable to form the laser diode ridge stripe parallel to the [11-2-3] direction for higher gain. The facet should therefore be orthogonal to the [11-2-3] direction. This facet orientation, however, does not cleave easily and yields are low. However, etched facets of (11-22) laser diodes are often rough and not orthogonal to the [11-2-3] direction.

Facet polishing can be used for laser diodes grown on semipolar or nonpolar orientations where facets orthogonal to the laser ridge/stripe are initially formed by cleaving or etching. Chemical mechanical and/or mechanical polishing of facets can be applied on any growth orientation. Moreover, chemical mechanical and/or mechanical polishing of the facets can lead to smooth and properly oriented facets. With the right polishing process, damage to the semiconductor device can be minimized.

What is needed, then, are improved techniques for polishing facets for semipolar and nonpolar (Al,In,B,Ga)N laser diodes. The present invention satisfies this need.

### SUMMARY OF THE INVENTION

To overcome the limitations in the prior art described above, and to overcome other limitations that will become apparent upon reading and understanding the present specification, the present invention discloses the use of chemical mechanical polishing and/or mechanical polishing for the formation of facets in (Al,In,B,Ga)N or III-nitride laser diodes grown epitaxially in semipolar and nonpolar orientations. This method of facet formation can be used for semipolar and nonpolar growth orientations where cleaving or etching of facets does not provide facets that are smooth and/or orthogonal to the laser ridge/stripe. This method of laser facet formation can also be applied to semipolar growth orientations where cleaving of facets orthogonal to the laser ridge/stripe is possible, but results in low yields.

### BRIEF DESCRIPTION OF THE DRAWINGS

Referring now to the drawings in which like reference numbers represent corresponding parts throughout:

FIG. 1 is a schematic showing one possible embodiment of a device structure fabricated according to the present invention.

FIG. 2 shows a sample being diced following the top side processing of the (Al,In,B,Ga)N laser diode in FIG. 1.

FIGS. 3(a) and 3(b) show a sample being polished following the dicing of the (Al,In,B,Ga)N laser diode in FIG. 2.

FIG. 4 shows Scanning Electron Microscope (SEM) images of a front view (top image) and cross-sectional view (bottom image) of a facet for a semipolar (11-22) (Al,In,B,Ga)N laser diode.

FIG. 5 is a graph that plots Power Output (mW) vs. Current Density (kA/cm²) for a 4×1200 μm² semipolar (11-22) (Al,In,B,Ga)N laser diode where the threshold current density Jₜₕ=9.94 kA/cm².

FIG. 6 is a graph that plots Intensity (a.u.) vs. Emission Wavelength (nm) for the semipolar (11-22) (Al,In,B,Ga)N laser diode of FIG. 5, which shows an emission wavelength of λ=457 nm with a full width at half maximum (FWHM)=0.6 nm.

FIG. 7 is a graph that plots the threshold current density Jₜₕ (kA/cm²) vs. Ridge Width (μm) for semipolar (11-22) (Al,In,B,Ga)N laser diodes that are 900 and 1200 μm in length having etched facets that are not polished.

FIG. 8 is a graph that plots the threshold current density Jₜₕ (kA/cm²) vs. Ridge Width (μm) for semipolar (11-22) (Al,In,B,Ga)N laser diodes that are 900 and 1200 μm in length having polished facets.

FIG. 9 is a flowchart that illustrates one embodiment of a process for fabricating a semipolar or nonpolar (Al,In,B,Ga)N laser diode with polished facets.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

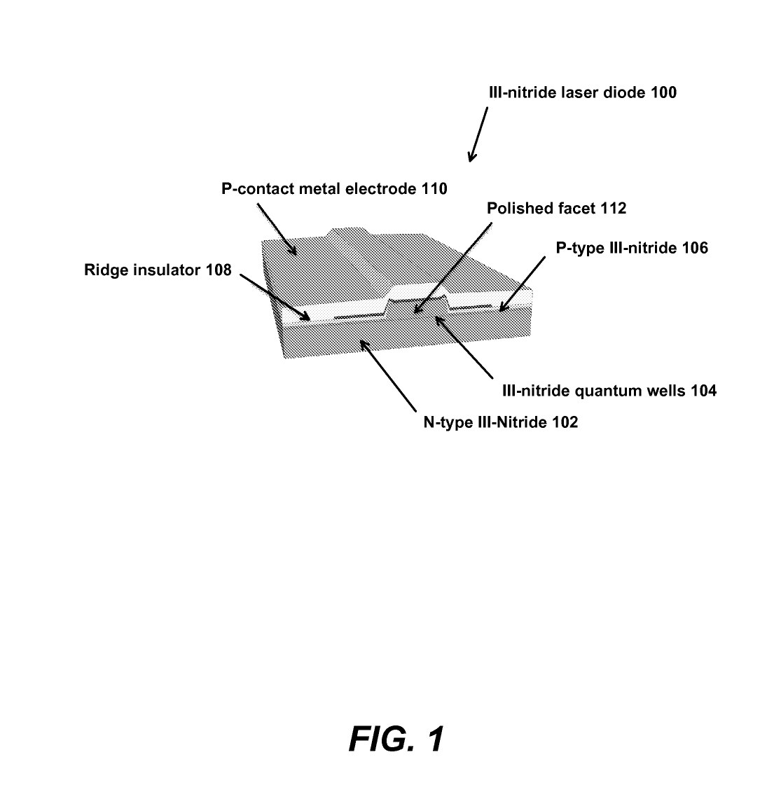

FIG. 1 is a schematic showing a light emitting device structure fabricated according to the present invention. Preferably, the light emitting device comprises a III-nitride laser diode epitaxially grown on a semipolar or nonpolar orientation substrate, i.e., on a growth surface of a substrate comprising a semipolar or nonpolar plane, wherein the III-nitride laser diode has one or more polished facets. In one embodiment, the III-nitride laser diode may be grown on a semipolar (11-22), (11-2-2), (101-1), (10-1-1), (20-21), (20-2-1), (30-31) or (30-3-1) orientation substrate. In another embodiment, the III-nitride laser diode may be grown on a nonpolar (10-10) or (11-20) orientation substrate. In either embodiment, the polished facets are chemically mechanically polished or mechanically polished.

In one embodiment, the III-nitride laser diode 100 comprises an edge-emitting, index guided, ridge structure grown epitaxially in a semipolar or nonpolar orientation on a substrate or template (not shown) using standard semiconductor lithography, etching and deposition processes. The laser diode 100 includes one or more N-type III-nitride layers 102, one or more III-nitride quantum wells 104, one or more P-type III-nitride layers 106, at least one Ridge insulator layer 108 deposited on the sidewall and field of the ridge but not directly on top of the ridge, at least one P-contact metal electrode 110, and at least one N-contact electrode (not shown). Other layers and structures may be present in the laser diode 100, but are omitted from the illustration of FIG. 1 for the sake of simplicity.

After fabrication of the device 100, facets 112 may be formed by cleaving or etching, wherein one or more of the facets 112 are then polished. Preferably, the polished facets 112 are orthogonal to a longitudinal axis of a resonant cavity of the III-nitride laser diode 100. In addition, the polished facets 112 preferably are smooth enough to serve as mirrors to form a Fabry-Perot cavity for the laser diode 100. The end result is an III-nitride laser diode 100 epitaxially grown on semipolar or nonpolar orientations with polished facets 112.

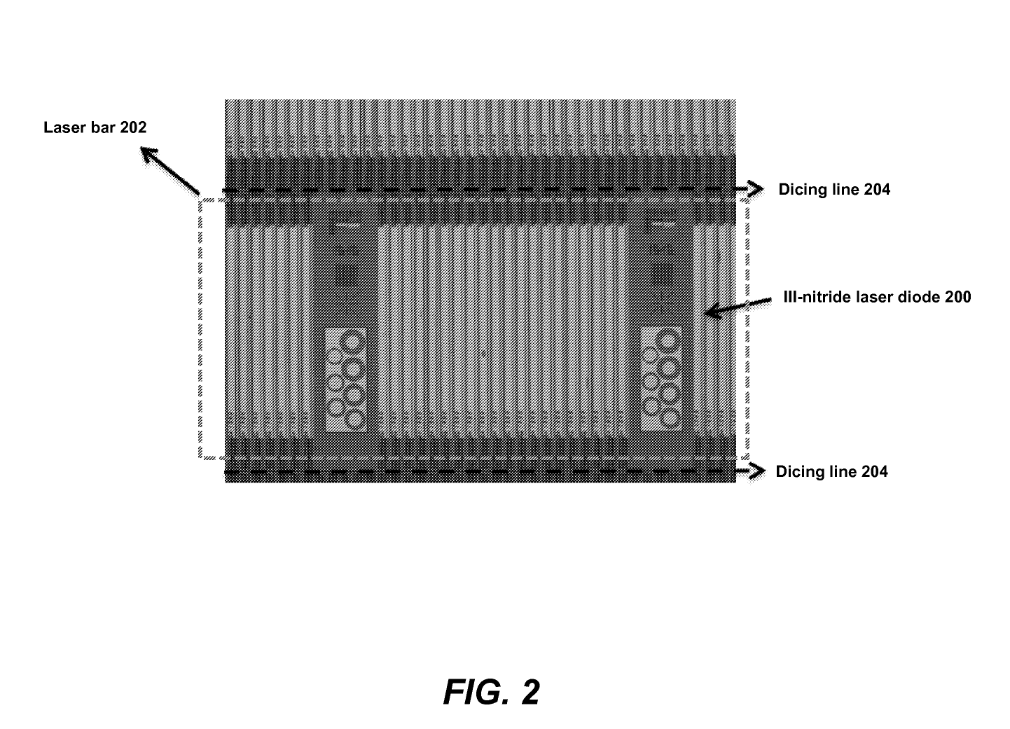

FIG. 2 shows a sample being diced following the top side processing of the III-nitride laser diode in FIG. 1. The sample containing the III-nitride laser diodes 200 is diced into bars 202, e.g., using a dicing saw made by ADT™, with the dicing line 204 direction orthogonal to the ridge stripe direction of the III-nitride laser diode 200. After the laser bars 202 are singulated by dicing, the facets of the III-nitride laser diode 200 may be polished.

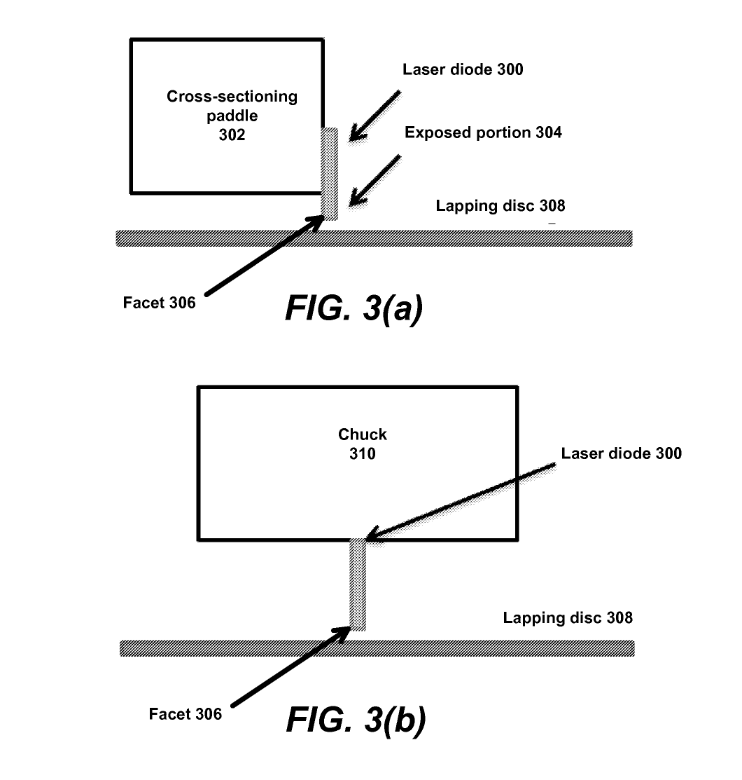

FIGS. 3(a) and 3(b) show a sample being polished following the dicing of the III-nitride laser diode in FIG. 2. Specifically, FIGS. 3(a) and 3(b) illustrate alternative techniques for mounting the III-nitride laser diode 300, e.g., on an Allied High Tech Multi-Prep™ polishing system.

In one example, FIG. 3(a) illustrates how the III-nitride laser diode 300 is mounted on a cross-sectioning paddle 302 using, for example, hot mounting wax (not shown), such that a portion 304 of the III-nitride laser diode 300 is exposed, as one end, i.e., a facet 306, of the III-nitride laser diode 300 is processed by a polishing or lapping disc 308. In this embodiment, the position of the cross-sectioning paddle 302 is used in order to monitor the polish depth as the lapping disc 308 processes the facet 306 of the III-nitride laser diode 300.

In another example, FIG. 3(b) illustrates how the III-nitride laser diode 300 is mounted on a chuck 310 using, for example, hot mounting wax (not shown), such that the entirety of the III-nitride laser diode 300 is exposed, as one end, i.e., a facet 306, of the III-nitride laser diode 300 is processed by the lapping disc 308. In this embodiment, the position of the chuck 310 is used in order to monitor the polish depth as the lapping disc 308 processes the facet 306 of the III-nitride laser diode 300.

In both FIGS. 3(a) and 3(b), the facet 306 is polished mechanically using a sequence of lapping discs 308 that successively have smaller grit sizes to remove material damaged by a dicing saw and to eventually form smooth and properly oriented facets 306 on the III-nitride laser diode 300.

For example, Table 1 below describes a sequence of lapping discs with successively smaller grit sizes indicating the amount of material removed from the sample by the polishing according to the lapping discs' grit size and specifying the abrasive material of each of the lapping discs.

TABLE 1
Sequence of lapping discs used to remove an amount X μm of material

| Amount X of material | Lapping disc | Abrasive material of |
|---|---|---|
| removed by polishing (μm) | grit size (μm) | lapping disc |
| ~70 | 6 | Diamond |
| ~25 | 3 | Diamond |
| ~10 | 1 | Diamond |
| 4 | 0.3 | Al₂O₃ |
| 1 | 0.05 | Al₂O₃ |
| 1 | 0.02 | SiO₂ |

In one embodiment, the polishing techniques can be determined after surveying the available semiconductor dicing and polishing equipment. For example, limitations of the tools can be determined and then a new set of lithography masks for laser fabrication can be designed based on those limitations.

Experimental Results

In order to measure the performance of the polished facets, the inventors fabricated III-nitride laser diodes on a wafer in a semipolar (11-22) orientation and cleaved the wafer in two. On one half of the wafer, semipolar (11-22) III-nitride laser diodes were fabricated with mechanically polished facets. On another half of the wafer, semipolar (11-22) III-nitride laser diodes were fabricated with facets formed only by dry-etching with no polishing.

The semipolar (11-22) III-nitride laser diodes were grown on stress relaxed InGaN waveguiding layers with electron/hole blocking layers, wherein the epitaxial and device structure of the laser diodes is described in U.S. Utility application Ser. No. 13/659,191, filed Oct. 24, 2012, by Matthew T. Hardy, Po Shan Hsu, Steven P. DenBaars, James S. Speck, and Shuji Nakamura, entitled “A HOLE BLOCKING LAYER FOR THE PREVENTION OF HOLE OVERFLOW AND NON-RADIATIVE RECOMBINATION AT DEFECTS OUTSIDE THE ACTIVE REGION,” attorney's docket number 30794.434-US-U1 (2012-239), cross-referenced above, which application is incorporated by reference herein.

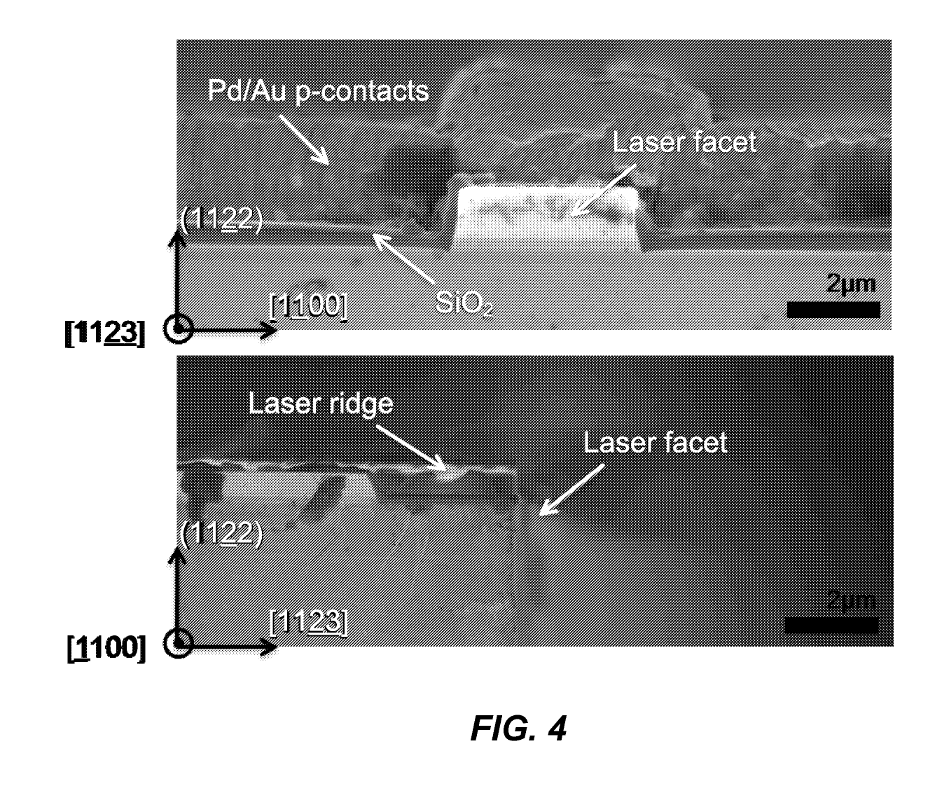

FIG. 4 shows Scanning Electron Microscope (SEM) images of a front view (top image) and cross-sectional view (bottom image) of a facet for a semipolar (11-22) III-nitride laser diode.

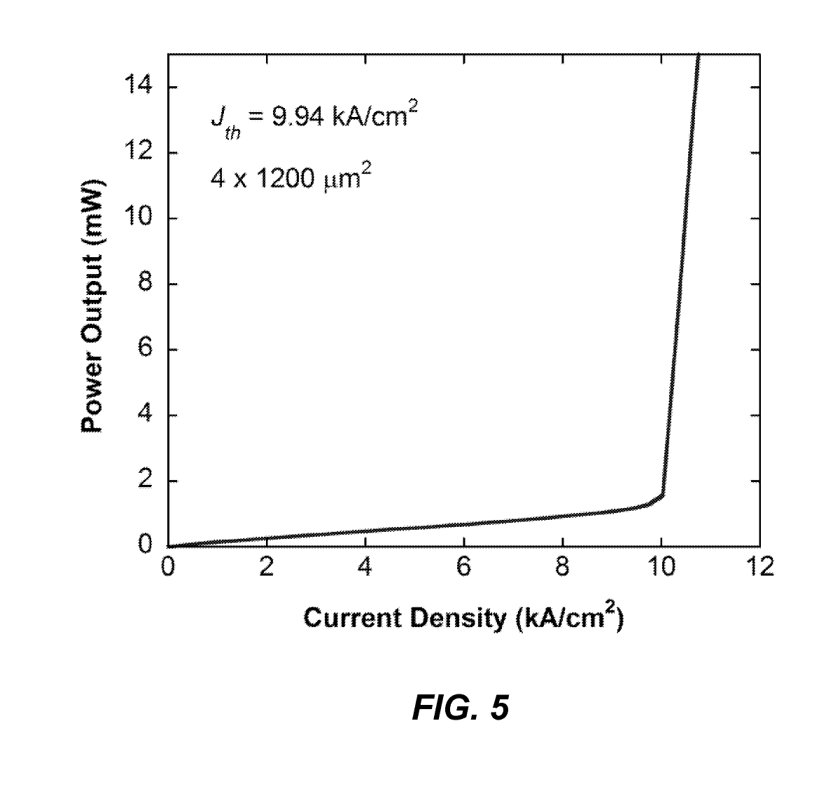

FIG. 5 is a graph that plots Power Output (mW) vs. Current Density (kA/cm²) for a 4×1200 μm² semipolar (11-22) III-nitride laser diode where the threshold current density Jₜₕ=9.94 kA/cm².

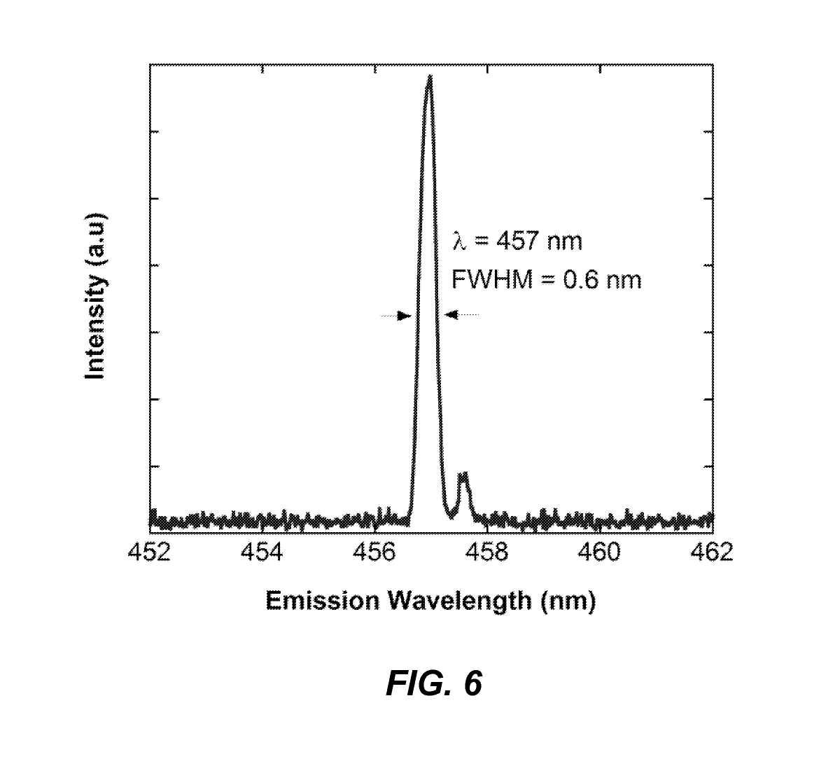

FIG. 6 is a graph that plots Intensity (a.u.) vs. Emission Wavelength (nm) for the semipolar (11-22) III-nitride laser diode of FIG. 5, which shows an emission wavelength of λ=457 nm with a full width at half maximum (FWHM)=0.6 nm.

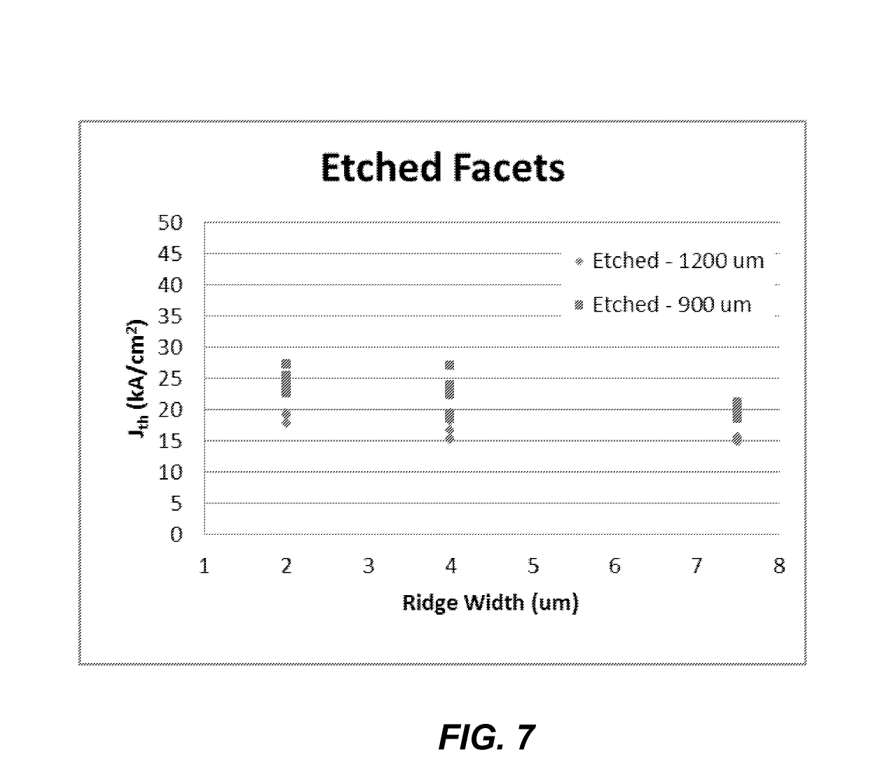

FIG. 7 is a graph that plots the threshold current density Jₜₕ (kA/cm²) vs. Ridge Width (μm) for semipolar (11-22) III-nitride laser diodes that are 900 and 1200 μm in length having etched facets that are not polished.

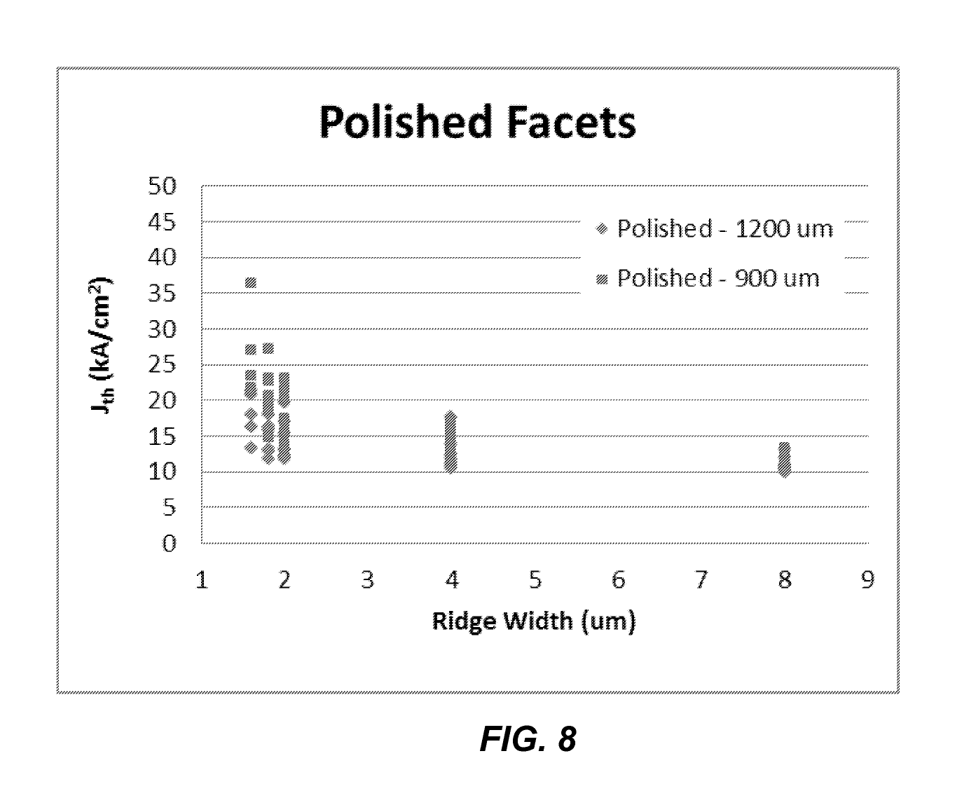

FIG. 8 is a graph that plots the threshold current density Jₜₕ (kA/cm²) vs. Ridge Width (μm) for semipolar (11-22) III-nitride laser diodes that are 900 and 1200 μm in length having polished facets.

It can be seen from FIGS. 7 and 8 that the semipolar (11-22) III-nitride laser diodes having polished facets have lower threshold current densities Jₜₕ as compared to semipolar (11-22) III-nitride laser diodes having etched facets that are not polished.

Process Flowchart

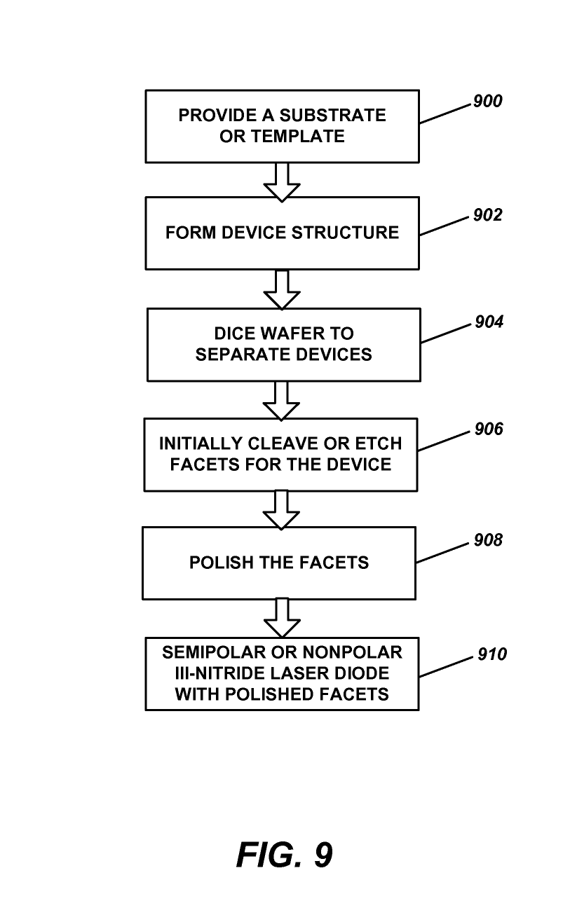

FIG. 9 is a flowchart that illustrates a method for fabricating a light emitting device comprising epitaxially growing an III-nitride laser diode on a semipolar or nonpolar orientation, and polishing one or more facets of the III-nitride laser diode. The fabrication of the device may use well-established semiconductor device processing techniques, including lithography, etching and deposition processes.

Block 900 represents the step of providing a substrate or template, such as a sapphire, SiC, or bulk GaN substrate or template. The substrate or template may comprise a wafer, and multiple semipolar or nonpolar III-nitride laser diodes may be fabricated.

Block 902 represents the step of epitaxially forming the device structure in a semipolar or nonpolar orientation on or above the substrate or template, which includes at least fabricating one or more N-type III-nitride layers, one or more III-nitride quantum wells, one or more P-type III-nitride layers, at least one Ridge insulator layer, at least one P-contact electrode, and at least one N-contact electrode. Other layers and structures may be fabricated in the laser diode as well.

Block 904 represents the step of processing the wafer to separate the individual semipolar or nonpolar III-nitride laser diodes. Specifically, this step comprises dicing the III-nitride laser diode into a bar using a dicing line direction orthogonal to a ridge stripe direction of the III-nitride laser diode.

Block 906 represents the step of initially cleaving or etching the facets for each of the individual semipolar or nonpolar III-nitride laser diodes.

Block 908 represents the step of polishing the facets for each of the individual semipolar or nonpolar III-nitride laser diodes using one or more lapping discs.

In one embodiment, Block 908 may represent the step of mounting the III-nitride laser diode on a cross-sectioning paddle, such that a portion of the III-nitride laser diode is exposed, as one of the facets of the III-nitride laser diode is polished by the lapping discs. In this embodiment, a position of the cross-sectioning paddle is used to monitor a polish depth as the lapping discs polish one of the facets of the III-nitride laser diode.

In another embodiment, Block 908 may represent the step of mounting the III-nitride laser diode on a chuck, such that an entirety of the III-nitride laser diode is exposed, as one of the facets of the III-nitride laser diode is polished by the lapping discs. In this embodiment, a position of the chuck is used to monitor a polish depth as the lapping discs polish one of the facets of the III-nitride laser diode.

In both embodiments, the facets may be polished using a sequence of the lapping discs with successively smaller grit sizes to remove material from the facets of the III-nitride laser diode and to form smooth and vertical facets on the III-nitride laser diode. The sequence of lapping discs my be comprised of an abrasive material selected from diamond, Al₂O₃ and SiO₂; the successively smaller grit sizes may range from about 6 μm to about 0.02 μm; and the material removed from the facets may range from about 70 μm to about 1 μm.

Block 910 represents the end result of the process steps, namely, one or more III-nitride laser diodes epitaxially grown on semipolar or nonpolar orientations, wherein each of the III-nitride laser diodes has a cavity bounded by facets, and the facets are polished facets that are positioned appropriately and are sufficiently smooth to support oscillation of optical modes within the cavity. Preferably, the polished facets are smooth enough to serve as mirrors to form a Fabry-Perot cavity for the semipolar or nonpolar III-nitride laser diodes. Moreover, the semipolar or nonpolar III-nitride laser diodes with polished facets have lower threshold current densities as compared to semipolar or nonpolar III-nitride laser diodes with facets that are not polished.

Possible Modifications and Variations

The III-nitride laser diodes of the present invention can be grown on any semipolar orientation, such as the (11-22), (11-2-2), (101-1), (10-1-1), (20-21), (20-2-1), (30-31), or (30-3-1) orientations, etc. In addition, the III-nitride laser diodes of the present invention can be grown on any nonpolar orientation, such as the (10-10) or (11-20) orientations.

Any number of different techniques for polishing the facets for the III-nitride laser diodes can be used. Specifically, chemical mechanical polishing or mechanical polishing techniques other than those disclosed herein may be used.

The abrasive material used for polishing may also vary. Some examples of possible abrasive materials include diamond, aluminum oxide, boron nitride, silicon dioxide, silicon carbide, etc.

In addition, one or both of the facets may be polished at an angle and thus may not be orthogonal to a longitudinal axis of the resonant cavity of the III-nitride laser diode. Such facets may be used in other types of lasers, such as superluminescence diodes.

Advantages and Improvements

One advantage of the present invention is that chemical mechanical and/or mechanical polishing of facets results in smooth and properly oriented, i.e., vertical, facets for semipolar or nonpolar III-nitride laser diodes. Specifically, the present invention overcomes the problem that the desired facet surface and orientation may not be easily formed by cleaving or etching of semipolar or nonpolar III-nitride laser diodes.

Another advantage of the present invention is that, with the right polishing process, damage to the semiconductor material of the semipolar or nonpolar III-nitride laser diodes can be minimized.

Still another advantage of the present invention is that chemical mechanical and/or mechanical polishing of facets can be applied on any growth orientation.

Nomenclature

The terms “(Al,In,B,Ga)N” or “Group-III nitride” or “III-nitride” or “nitride” as used interchangeably herein refer to any composition or material related to (Al,In,B,Ga)N semiconductors having the formula Al_{w}InₓB_{y}Ga_{z}N where 0≦w≦1, 0≦x≦1, 0≦y≦1, 0≦z≦1, and w+x+y+z=1. These terms as used herein are intended to be broadly construed to include respective nitrides of the single species, Al, In, B, Ga, as well as binary, ternary and quaternary compositions of such Group III metal species. When two or more of the (Al,In,B,Ga)N component species are present, all possible compositions, including stoichiometric proportions as well as off-stoichiometric proportions (with respect to the relative mole fractions present of each of the (Al,In,B,Ga)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of Group-III nitrides. When identifying crystal orientations, directions, terminations and polarities using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

Many Group-III nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in Group-III nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. For example, semipolar {11-2n} (where n can assume any value, e.g., 2,-2) or semipolar {10-1l} (where l can assume values such as 1, −1, 3, −3, etc.). Subsequent semipolar layers are equivalent to one another, so the crystal will have reduced polarization along the growth direction.

### REFERENCES

The following references are incorporated by reference herein:

[1] Shuji Nakamura, Stephen Pearton, Gerhard Fasol, The Blue Laser Diode, Second Edition, Springer-Verlag 2000.

[2] Larry Coldren and Scott Corzine, Diode Lasers and Photonic Integrated Circuits, John Wiley 1995.

[3] Nakamura et al., InGaN Multi Quantum Well Structure Laser Diodes with Cleaved Mirror Facets, Jpn. J. Appl. Phys. 35 (1996) pp. L217-L220 (doi: 10.1143/JJAP.35.L217).

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A light emitting device, comprising:
a III-nitride based laser diode epitaxially grown on or above a semipolar or nonpolar orientation substrate, wherein the III-nitride based laser diode has one or more polished facets.

2. The device of claim 1, where the III-nitride based laser diode is grown on a semipolar (11-22), (11-2-2), (101-1), (10-1-1), (20-21), (20-2-1), (30-31) or (30-3-1) orientation.

3. The device of claim 1, where the III-nitride based laser diode is grown on a nonpolar (10-10) or (11-20) orientation.

4. The device of claim 1, where the polished facets are chemically mechanically polished.

5. The device of claim 1, where the polished facets are mechanically polished.

6. The device of claim 1, where one or more of the polished facets are orthogonal to a longitudinal axis of a resonant cavity of the III-nitride based laser diode.

7. The device of claim 1, where one or more of the polished facets are polished at an angle and are not orthogonal to a longitudinal axis of a resonant cavity of the III-nitride based laser diode.

8. A method for fabricating a light emitting device, comprising:
epitaxially growing a III-nitride based laser diode on or above a semipolar or nonpolar orientation substrate; and
polishing one or more facets of the III-nitride based laser diode.

9. The method of claim 8, further comprising
dicing the III-nitride based laser diode into a bar using a dicing line direction orthogonal to a ridge stripe direction of the III-nitride based laser diode; and
polishing the facets of the III-nitride based laser diode after the III-nitride based laser diode is diced into the bar using one or more lapping discs.

10. The method of claim 9, further comprising
mounting the III-nitride based laser diode on a cross-sectioning paddle, such that a portion of the III-nitride based laser diode is exposed, as one of the facets of the III-nitride based laser diode is polished by the lapping discs.

11. The method of claim 10, wherein a position of the cross-sectioning paddle is used to monitor a polish depth as the lapping discs polish one of the facets of the III-nitride based laser diode.

12. The method of claim 9, further comprising:
mounting the III-nitride based laser diode on a chuck, such that an entirety of the III-nitride based laser diode is exposed, as one of the facets of the III-nitride based laser diode is polished by the lapping discs.

13. The method of claim 12, wherein a position of the chuck is used to monitor a polish depth as the lapping discs polish one of the facets of the III-nitride based laser diode.

14. The method of claim 9, wherein the facets are polished using a sequence of the lapping discs with successively smaller grit sizes to remove material from the facets of the III-nitride based laser diode and to form smooth and vertical facets on the III-nitride based laser diode.

15. The method of claim 14, wherein the successively smaller grit sizes range from about 6 μm to about 0.02 μm.

16. The method of claim 14, wherein the material removed from the facets range from about 70 μm to about 1 μm.

17. The method of claim 14, wherein the sequence of lapping discs are comprised of an abrasive material selected from diamond, Al₂O₃ and SiO₂.

18. The method of claim 8, wherein the semipolar or nonpolar III-nitride based laser diodes with polished facets have lower threshold current densities as compared to semipolar or nonpolar III-nitride based laser diodes with facets that are not polished.

19. A light emitting device, comprising:
III-nitride based laser diode epitaxially grown on or above a semipolar or nonpolar orientation substrate, wherein the III-nitride based laser diode has a cavity bounded by facets, and the facets are polished facets that are positioned appropriately and are sufficiently smooth to support oscillation of optical modes within the cavity.
